(19) United States
(12) Patent Application Publication
(10) Pub. No.: US 2006/0134865 A1
(43) Pub. Date: Jun. 22, 2006

(54) Method of manufacturing a semiconductor device

(75) Inventors: Hiroyuki Inuzuka, Fukuyama-shi Hiroshima (JP); Tsukasa Doi, Fukuyama-shi Hiroshima (JP); Kazumasa Mitsumune, Kurashiki-shi Okayama (JP)

Correspondence Address: EDWARDS & ANGELL, LLP, P.O. BOX 55874, BOSTON, MA, 02205, US

(73) Assignee: Sharp Kabushiki Kaisha, Osaka-shi (JP)

(21) Appl. No.: 11/303,583

(22) Filed: Dec. 14, 2005

(30) Foreign Application Priority Data
Dec. 17, 2004 (JP) 2004-366473

(51) Int. Cl. H01L 21/336; H01L 21/44

(52) U.S. Cl. 438/257; 438/672

(57) ABSTRACT

According to the present invention, a method of manufacturing a semiconductor device which comprises a matrix of memory cells of the floating gate type is provided in which the silicon nitride layer is deposited as an etching stop layer on a control gate electrode for bottom borderless contact process with the threshold voltage of transistor arrangements being controlled not to change so that the productivity can remain not declined. In particular, the silicon nitride layer (115) is deposited as an etching stop layer on the control gate electrode (105) for bottom borderless contact process so that the concentration of hydrogen (H₂) therein stays in a range from 1.5×10²¹ to 2.6×10²¹ atoms/cm³. Also, the silicon nitride layer (115) is deposited at a temperature of not higher than 700° C. by a low pressure CVD technique.

### CROSS REFERENCE TO RELATED APPLICATTION

This Nonprovisional application claims priority under 35 U.S.C. §119(a) on Patent Application No. 2004-366473 filed in Japan on Dec. 17, 2004, the entire contents of which are hereby incorporated by reference.

### BACKGROUND OF THE INVENTION

1. Field of the Invention

The present invention relates to a method of manufacturing a semiconductor device through a step of depositing a silicon nitride layer for bottom borderless contact process.

2. Description of the Related Art

As large scale integrated circuit (LSI) devices become increasingly highly densified and integrated, a silicon nitride layer has been utilized as a diffusion layer for a contact hole opening in an upper inter-layer insulating layer or an etching stop layer over a self-aligned silicide layer, in order to bring the diffusion layer and the self-aligned silicide layer into contact with an upper wiring metal.

FIG. 7 is a cross sectional view of a gate electrode structure in a memory cell of floating gate type in a conventional semiconductor device (such as a nonvolatile memory device) in a manufacturing step. More particularly, FIG. 7(A) illustrates the cross section in the manufacturing step. only of the floating gate structure including a floating gate 203, an insulating layer 204, and a control gate 205 that are formed over a semiconductor substrate 201 (hereinafter referred to as the substrate 201) via a gate oxide layer 202, for convenience. FIG. 7(B) illustrates a cross section in the manufacturing step of a state of the floating gate structure in FIG. 7(A), where a side wall insulating layer 208 is formed on each side wall of the gate electrode structure constituted from the floating gate 203, insulating layer 204 and control gate 205, source/drain regions 207 is formed at both sides of the gate electrode on the substrate 201, silicide layers 210 and 213 are self-aligningly formed respectively on the control gate 205 and the source/drain regions 207, a silicon nitride layer 215 and an upper inter-layer insulating layer 216 are formed over an entire surface of the side wall insulating layers 208 and the silicide layers 210 and 213, and the silicide layer 213 on the source/drain region 207 has a contact opening 217. The silicon nitride layer 215 shown in FIG. 7(B) serves as the etching stop layer for the contact opening 217.

The silicon nitride layer 215 provided beneath the inter-layer insulating layer 216 interrupts dispersion of water from the upper inter-layer insulating layer 216 and prevents the water from being supplied to a surface of the substrate 201 on which elements are formed. Also, the silicon nitride layer 215 prevents the diffusion layer 207 or the self-aligned silicide layers 210 and 213 from being over-etched during opening of the contact hole 217 in the inter-layer insulating layer 216. In other words, when the contact holes are simultaneously opened in the self-aligned silicide layers 210 and 213 on the control gate 205 and the source/drain region 207 by an etching process, it is possible to etch the self-aligned silicide layers 210 and 213 to open the contact holes to be different in the depth by having the silicon nitride layer 215 serve as the etching stop layer, by setting a condition where the silicon nitride layer 215 is hard to be etched to the inter-layer insulating layer 216 while the inter-layer insulating layer 216 is etched to different depths. As the inter-layer insulating layer 216 has been etched, portions of the silicon nitride are removed from the contact holes. One of the conventional methods of manufacturing a semiconductor device with the silicon nitride layer 215 using as an etching stop layer is typically disclosed in Japanese Patent Laid-Open Publication No. 2004-228589.

Conventionally, the silicon nitride layer is commonly deposited by a plasma CVD technique or a low pressure CVD technique. However, the silicon nitride layer deposited by the plasma CVD technique is 50% or lower in the step coverage particularly at an advanced semiconductor device of not older than the 0.13 μm generation, as compared with that of the silicon nitride layer deposited by the low pressure CVD technique, which is almost 100%. This causes the inter-layer insulating layer to be implanted with much difficulty when the etching stop layer for bottom borderless contact process, such as self-aligned contact arrangement, is deposited to a required thickness. Thus, it is desirable to deposit the silicon nitride layer by the low pressure CVD technique with which a high step coverage can be obtained even when the miniaturization is advanced.

However, the deposition of a silicon nitride layer by the low pressure CVD technique has the following drawback. Using the low pressure CVD technique, a silicon nitride layer is generally deposited at a temperature of around 760° C., and active hydrogen is produced during the depositing diffuse to the channel regions and the diffusion layer. This causes fluctuation in the threshold voltage of the transistor arrangement, and results in a decrease in yield.

### SUMMARY OF THE INVENTION

The present invention has been developed in view of the above problem. An object of the present invention is to provide a method of manufacturing a semiconductor device provided with memory cells of the floating gate type, where the silicon nitride layer is deposited on a control gate electrode as an etching stop layer for bottom borderless contact process while suppressing fluctuation in threshold voltage of transistor arrangement and without causing a decrease in yield.

In order to the above object of the present invention, a method of manufacturing a semiconductor device which comprises a matrix of memory cells, each memory cell including source and drain regions provided on a semiconductor substrate and a layer construction of a gate insulating layer, a floating gate, another insulating layer, and a control gate deposited on a channel region located between the source and drain regions, is provided wherein the concentration of hydrogen in a silicon nitride layer deposited on the control gate electrode as the etching stop layer for bottom borderless contact process stays in a range from 1.5×10²¹ to 2.6×10²¹ atoms/cm³.

The method of manufacturing a semiconductor device may be modified in which the silicon nitride layer is deposited to cover entirely the control gate electrode and the source and drain regions.

Also, the method of manufacturing a semiconductor device may be modified in which the silicon nitride layer is deposited at a temperature of not higher than 700° C. by a low pressure CVD technique. Preferably, the silicon nitride layer is deposited with a thickness of 15 to 60 nm.

Moreover, the method of manufacturing a semiconductor device may be modified in which before the silicon nitride layer is deposited, a pattern of metal salicide layer is selectively developed on the surfaces of the control gate electrode and the source and drain regions.

Furthermore, the method of manufacturing a semiconductor device may be modified in which the silicon nitride layer is deposited at a temperature of not higher than 700° C. or preferably from 500° C. to 700° C. by using a material combination of mono-silane and ammonium gas. More preferably, the silicon nitride layer is deposited at a flow ratio of ammonium gas to mono-silane ranging from 25 to 133.

The method of manufacturing a semiconductor device may be modified in which the silicon nitride layer is deposited at a temperature of not higher than 700° C. or preferably from 500° C. to 650° C. by using a material combination of di-silane and ammonium gas. More preferably, the silicon nitride layer is deposited at a flow ratio of ammonium gas to di-silane ranging from 25 to 350.

### BRIEF DESCRIPTION OF THE DRAWINGS

FIG. 1 is a cross sectional view at a step, where two vertical cross sections which intersect at a right angle to each other are illustrated, explaining the action of developing a memory cell transistor arrangement in a method of manufacturing a semiconductor device according to the present invention;

FIG. 2 is a cross sectional view at a step explaining the action of developing a peripheral circuit transistor arrangement in the method of manufacturing a semiconductor device according to the present invention;

FIG. 3 is a cross sectional view at a step explaining the action of providing contact holes at the memory cell region in the method of manufacturing a semiconductor device according to the present invention;

FIG. 4 is a cross sectional view at a step explaining the action of providing contact holes at the peripheral circuit region in the method of manufacturing a semiconductor device according to the present invention;

FIG. 5 is a graph showing the relationship between the concentration of hydrogen in the silicon nitride layer, which is varied, and the threshold voltage in a peripheral circuit p+ region;

FIG. 6 is a graph showing the relationship between the concentration of hydrogen in the silicon nitride layer, which is varied, and the rate of defectives of the flash memory semiconductor device; and

FIG. 7 is a cross sectional view at a step explaining the action of a conventional method developing a gate electrode structure at a memory cell of the floating gate type in a conventional nonvolatile semiconductor storage device.

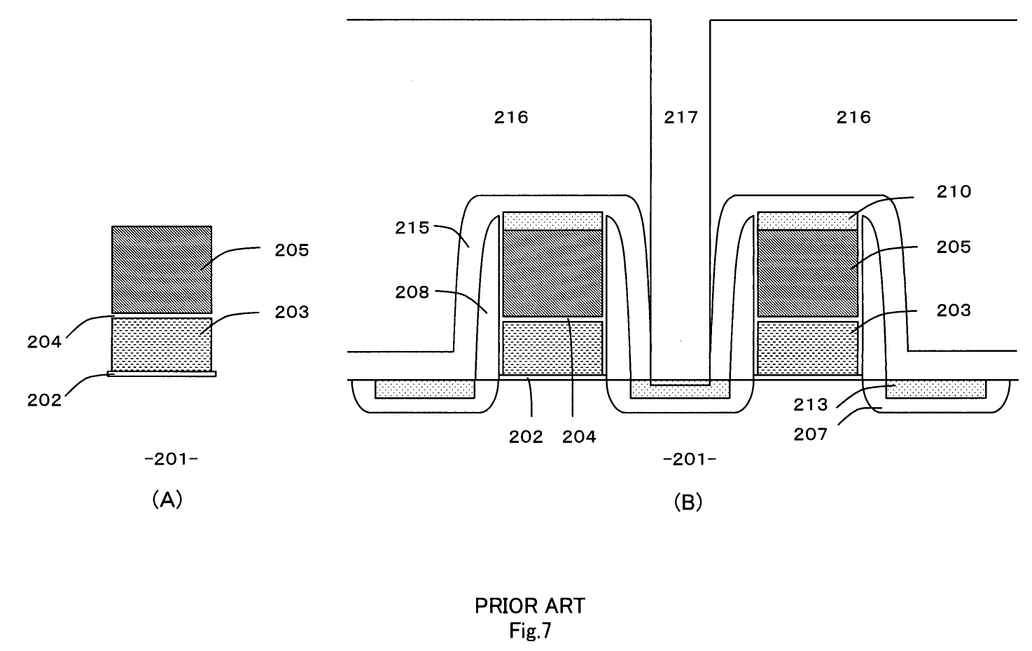

### DETAILED DESCRIPTION OF THE INVENTION

A method of manufacturing a semiconductor device (hereinafter referred to as an inventive method) according to the present invention will be described in more detail referring to the relevant drawings. It is noted that the semiconductor device manufactured by the inventive method as one embodiment of the present invention is a nonvolatile semiconductor storage device (flash memory) composed of a matrix of flash memory cells. It would also be understood that the inventive method is not limited to the following description.

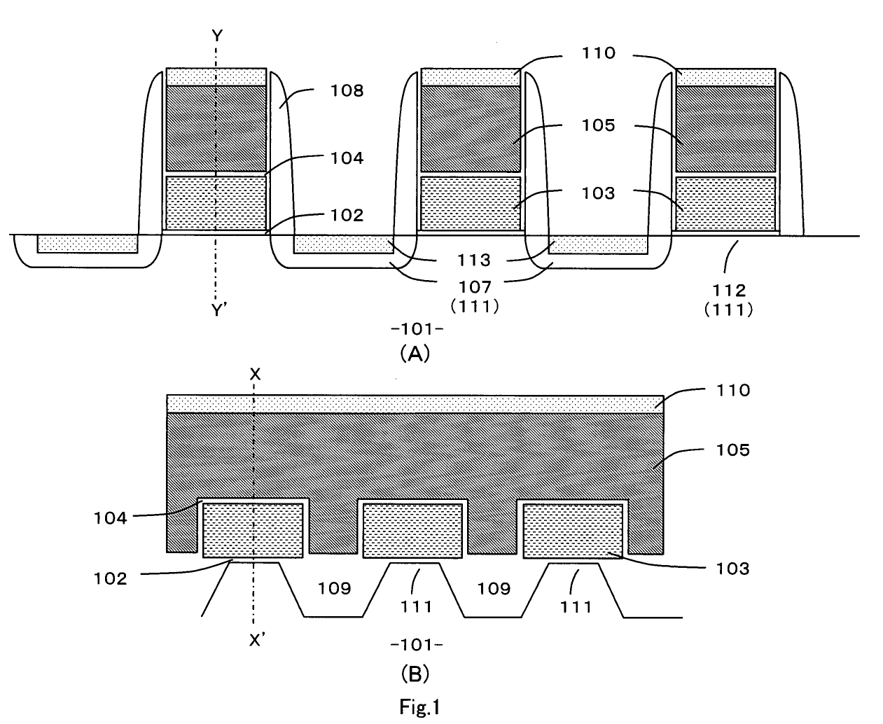

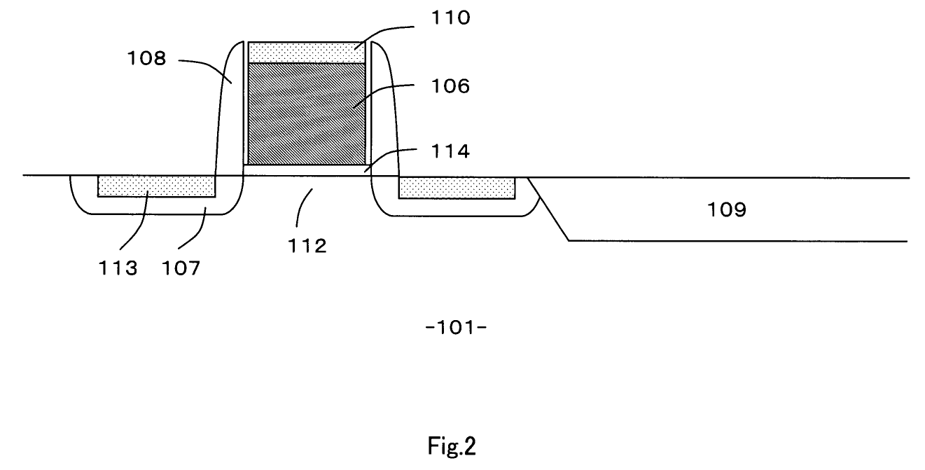

The description starts with a transistor structure of the memory cells and a relevant transistor structure of other peripheral circuits than the memory cells, referring to FIGS. 1 and 2.

FIG. 1(A) is a cross sectional view low pressure taken along the line X-X′ of FIG. 1(B) vertical to the direction of extension of control gates 105 which act as word lines including active regions 111, illustrating a row of the memory cells arranged repeatedly along the direction vertical to the direction of extension of the word lines. FIG. 1(B) is a cross sectional view low pressure taken along the line Y-Y′ of FIG. 1(A) parallel with the direction of extension of the word lines including floating gates 103 and the control gates 105, illustrating a row of the memory cells arranged repeated along the direction of extension of the word lines.

As shown in FIG. 1(B), the memory cells are formed on a p-type silicon substrate 101. More specifically, active regions 111 and element separating regions 109 are alternately provided on the upper surface of the p-type silicon substrate 101 by an STI (shallow trench isolation) technique. Also, as shown in FIG. 1(A), each of the active regions 111 incorporates a channel region 112 and source/drain regions 107 provided at both sides of the channel region 112. A tunnel oxide layer 102 is deposited on the channel region 112 as is covered with a floating gate 103 which consists mainly of a poly-silicone layer. The floating gate 103 is covered with a three-layer film (ONO layer) 104 which consists mainly of three, oxide, nitride, and oxide, layers. At the top, a control gate 105 composed of a cobalt silicide 110 (equivalent to a metal salicide) and a poly-silicone is developed on the ONO layer 104 so as to be self-aligned with the floating gate 103 along the direction vertical to the upper surface of the substrate 101 and parallel to the cross section taken along the line Y-Y′. In addition, as shown in FIG. 1(A), a cobalt silicide 113 is deposited on the surface of each of the source/drain region 107 as isolated from both sides by side wall insulating layers 108 in the form of oxide layers.

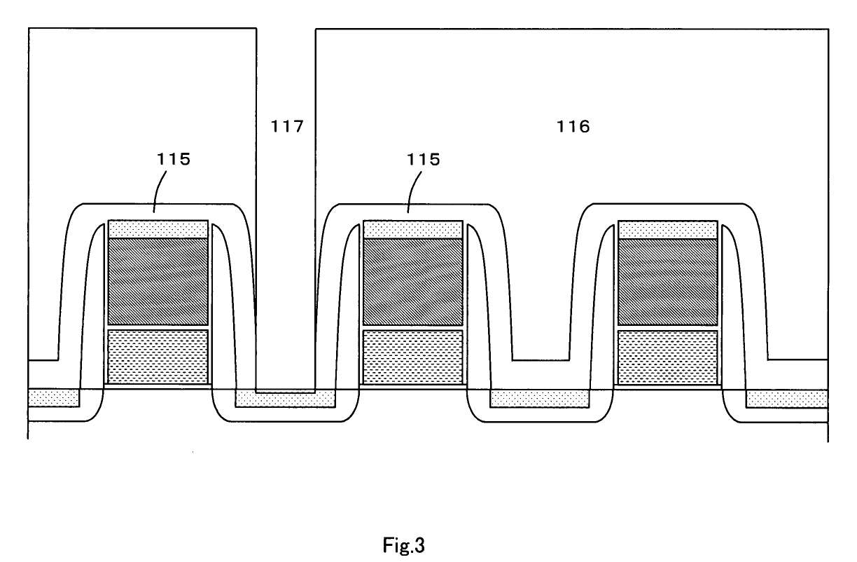

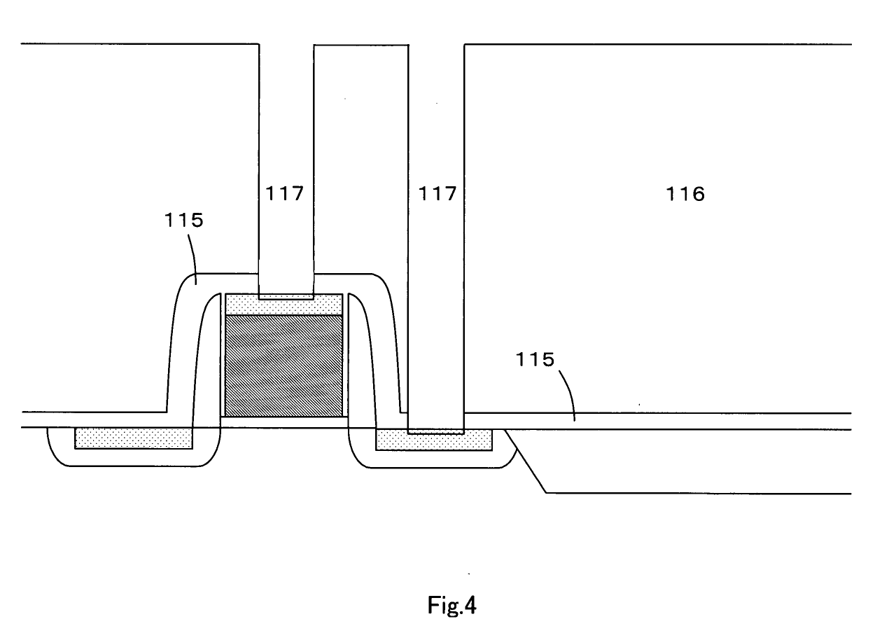

The transistor structure of peripheral circuits in the semiconductor device will now be described referring to the cross sectional view of FIG. 2. The transistor structure of peripheral circuits is also provided on the p-type silicon substrate 101. More specifically, when a gate electrode 106 consisting mainly of a cobalt silicide 110 and a poly-silicone been deposited on a gate oxide layer 114 which is greater in the thickness than the tunnel oxide layer 102 of the memory cells, source/drain regions 107 are provided at both sides of the channel region 112. A cobalt silicide 113 is then deposited on the upper surface of the source/drain region 107 as isolated from both sides by a side wall insulating layer 108. The transistor structure of each peripheral circuit is also isolated by the element separating region 109 from any other active region (not shown) or the transistor structure of another peripheral circuit. In FIG. 2, like components are denoted by like numerals as those of the memory cells shown in FIG. 1. Like components shown in FIGS. 3 and 4 are also denoted by like numerals for simplicity of the description.

The foregoing arrangement of the memory cell transistor structure and the peripheral circuit transistor structure shown in FIGS. 1 and 2 is followed by steps of depositing an etching stop layer 115 made of silicon nitride over the entire area of the memory cell regions and the peripheral circuit regions with the use of, for example, a low pressure CVD apparatus of single wafer type and of depositing an inter-layer insulating layer 116 made of, e.g., silicon oxide over the etching stop layer 115, as shown in FIGS. 3 and 4. Then, a pattern of resist layer (not shown) is deposited on the inter-layer insulating layer 116 to determine etching regions and subjected to an etching process at self-alignment for provide contact openings 117. FIG. 3 is a cross sectional view low pressure where the contact opening 117 is provided by etching the inter-layer insulating layer 116 down to the etching stop layer 115 on the transistor structure of each memory cell shown in FIG. 1(A). FIG. 4 is a cross sectional view low pressure where another contract opening 117 is provided by etching the inter-layer insulating layer 116 down to the etching stop layer 115 on the transistor structure of a peripheral circuit shown in FIG. 2.

Next, the foregoing steps of depositing and patterning the silicon nitride layer 115 with a low pressure CVD apparatus of single wafer type will be described.

The silicon material and nitrogen material of a gaseous form for depositing the silicon nitride layer may be mono-silane (SiH₄) or di-silane (Si₂H₆) and nitrogen (N₂) or ammonium (NH₃) respectively. Particularly, a combination of mono-silane and ammonium or a combination of di-silane and ammonium will be preferred as its reactive efficiency is optimum. The carrier gas may preferably be a nitrogen gas (N₂).

When the combination of mono-silane and ammonium is selected, the flow ratio of ammonium to mono-silane is set to 25-133. More particularly, mono-silane is 20 sccm when 2000 sccm of ammonium is taken. The temperature during the action of layer deposition is not higher than 700° C. or preferably in a range from 500° C. to 700° C., and 700° C., for example.

Alternatively, when the combination of di-silane and ammonium is selected, the flow ratio of ammonium to di-silane is set to 25-350. More particularly, di-silane is 20 sccm when 7000 sccm of ammonium is taken. The temperature during the action of layer deposition is not higher than 700° C. or preferably in a range from 500° C. to 700° C. or more preferably from 500° C. to 650° C., and 600° C., for example. The temperature of the substrate during the action of layer deposition is preferably as a low temperature as in a range from 500° C. to 700° C. The lower the temperature at which the silicon nitride is deposited, the higher the concentration of hydrogen in the layer will increase. Therefore, the temperature of the substrate is preferably set to 500° C. or higher. As the result, the concentration of hydrogen (H₂) in the silicon nitride layer can remain at a desirable level which will be explained later in more detail.

In case that a high-temperature processing action at 700° C. or higher is involved after the deposition of the silicide layers 110 and 113, some problems occur due to a lower level of the thermal resistance of the silicide layers. For example, the reaction between the silicide layer and the silicon layer will cause a change in the composition of the silicide layer. More specifically, the reduction between the silicide layer and thermally decomposed ammonium will decline the electrical conductivity or increase a stress in the silicide layer, thus generating unwanted voids. It is hence desired that the temperature at which the silicon nitride layer is deposited is not higher than 700° C.

The thickness of the silicon nitride layer as the etching stop layer 115 is preferably from 15 nm to 60 nm. With the etching stop layer 115 having a thickness enough to stop the etching across the inter-layer insulating layer 116, the silicon nitride layer 115 can readily be etched to provide the contact holes 117 through the inter-layer insulating layer 116.

After the layer deposition by the low pressure CVD method using the foregoing conditions (700° C. of the substrate temperature with the reaction gas composed of mono-silane and ammonium or 600° C. of the substrate temperature with the reaction gas composed of di-silane and ammonium), the concentration of hydrogen in the silicon nitride layer is measured to stay in a range from 0.08×10²¹ to 1.6×10²¹ atoms/cm³. On the contrary, the concentration of hydrogen in the silicon nitride layer deposited by a known plasma CVD method is measured ranging from 1.8×10²¹ to 3.16×10²¹ atoms/cm³ as is higher than that by the low pressure CVD method. It is also found that an amount of active hydrogen (H) generated during the layer deposition is migrated into the diffusion layer or channel region, hence producing a change in the threshold voltage of the transistor structure. It is further found that the productivity of flash memories is declined when the concentration of hydrogen is out of the permissive range. The measurement of the concentration of hydrogen in the silicon nitride layer is conducted using TDS and FT-IR technologies.

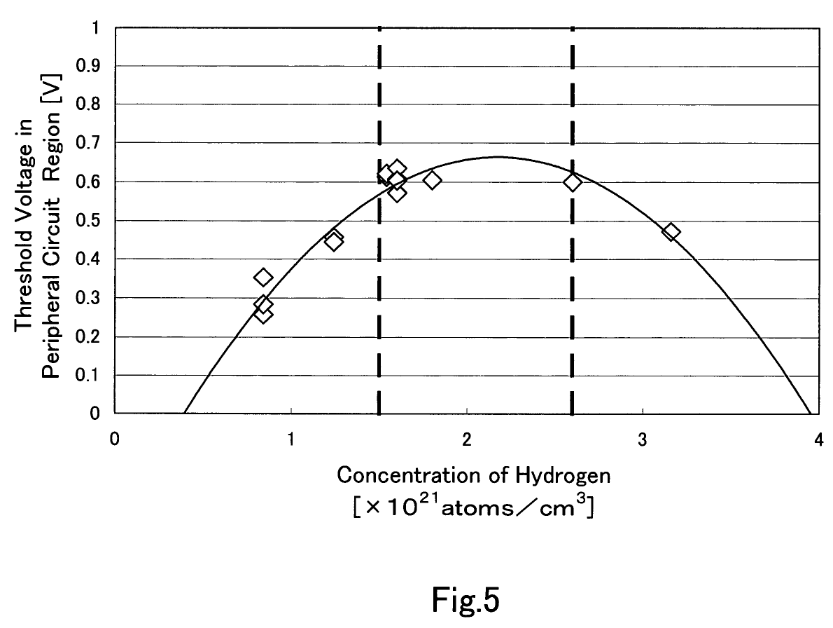

The relationship between the concentration of hydrogen in the silicon nitride layer, the threshold voltage (Vth) in the p+ region of the peripheral circuit, and the rate of defectives of the flash memory will now be described from the result of experiments. FIG. 5 illustrates a profile of the threshold voltage (Vth) in the p+ region of the peripheral circuit when the concentration of hydrogen in the silicon nitride layer is varied. As apparent from the result of experiments shown in FIG. 5, the threshold voltage soars close to 0.6 V when the concentration of hydrogen in the silicon nitride layer is varied from 1.5×10²¹ to 2.6×10²¹ atoms/cm³. Then, when the concentration of hydrogen in the silicon nitride layer is further increased from 2.6×10²¹ to 3.16×10²¹ atoms/cm³, the threshold voltage drops from 0.6 V to 0.5 V.

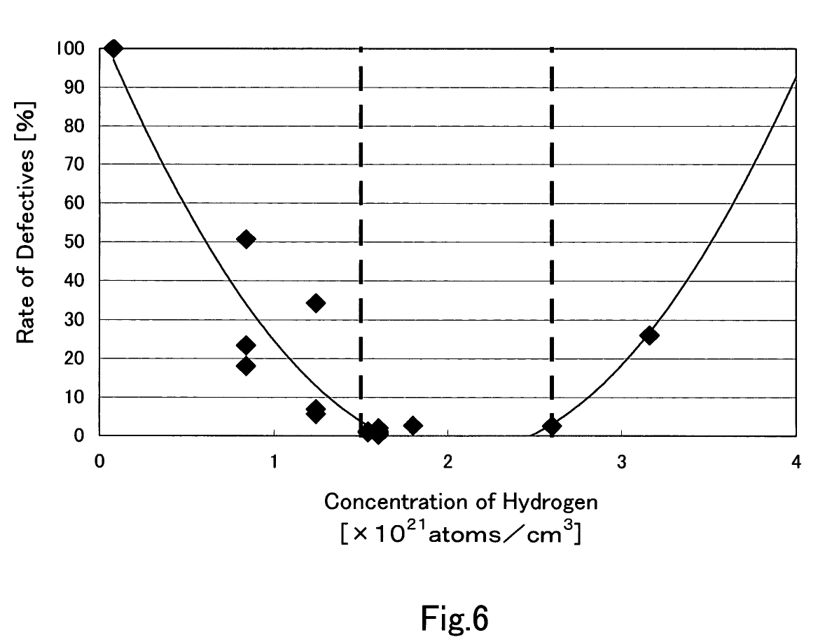

FIG. 6 illustrates the rate of defectives of the flash memory when the concentration of hydrogen in the silicon nitride layer is varied. As apparent from FIG. 6, the rate of defectives is as high as 100% when the concentration of hydrogen is 0.4×10²¹ atoms/cm³. When the concentration of hydrogen in the silicon nitride layer is increased from 1.5×10²¹ to 2.6×10²¹ atoms/cm³, the rate of defectives drops down to nearly 0%. If the concentration of hydrogen in the silicon nitride layer is further increased up to 3.16×10²¹ atoms/cm³, the rate of defectives will soar to around 30%.

As is proved from the series of experiments, a desired level of the concentration of hydrogen in the silicon nitride layer in the flash memory exists for implementing both an increase in the threshold voltage of the peripheral circuit p+ region and a decrease in the rate of defectives of the flash memory. The concentration of hydrogen is desired to stay in a range from 1.5×10²¹ to 2.6×10²¹ atoms/cm³. When its silicon nitride layer is deposited with the concentration of hydrogen thereof ranging from 1.5×10²¹ to 2.6×10²¹ atoms/cm³, the flash memory or nonvolatile semiconductor device can be improved in the productivity.

In brief, the inventive method of manufacturing a nonvolatile semiconductor device allows the silicon nitride layer which acts as an etching stop layer for use in the bottom borderless contact process to be controlled at a lower temperature and held to a desired range in the concentration of hydrogen, hence successfully minimizing a change in the threshold voltage of the p+ region of the peripheral circuits and a decrease in the productivity. Also, the method employing a low pressure CVD technique which is favorable for improving the step coverage during the deposition of the silicon nitride layer can contribute to the down-scaling of the products.

Although the present invention has been described in terms of a preferred embodiment, it will be appreciated that various modifications and alterations might be made by those skilled in the art without departing from the spirit and scope of the invention. The invention should therefore be measured in terms of the claims which follow.

What is claimed is:

1. A method of manufacturing a semiconductor device which comprises a matrix of memory cells, each memory cell including source and drain regions provided on a semiconductor substrate and a layer construction of a gate insulating layer, a floating gate, another insulating layer, and a control gate deposited on a channel region located between the source and drain regions, wherein
the concentration of hydrogen in a silicon nitride layer deposited on the control gate electrode as the etching stop layer for bottom borderless contact process stays in a range from 1.5×10²¹ atoms/cm³ to 2.6×10²¹ atoms/cm³.

2. The method of manufacturing a semiconductor device according to claim 1, wherein
the silicon nitride layer is deposited to cover entirely the control gate electrode and the source and drain regions.

3. The method of manufacturing a semiconductor device according to claim 1, wherein
the silicon nitride layer is deposited at a temperature of not higher than 700° C. by a low pressure CVD technique.

4. The method of manufacturing a semiconductor device according to claim 1, wherein
the silicon nitride layer is deposited with a thickness of 15 nm to 60 nm.

5. The method of manufacturing a semiconductor device according to claim 1, wherein
before the silicon nitride layer is deposited, a pattern of metal salicide layer is selectively developed on the surfaces of the control gate electrode and the source and drain regions.

6. The method of manufacturing a semiconductor device according to claim 1, wherein
the silicon nitride layer is deposited at a temperature of not higher than 700° C. by using a material combination of mono-silane and ammonium gas.

7. The method of manufacturing a semiconductor device according to claim 1, wherein
the silicon nitride layer is deposited at a temperature ranging from 500° C. to 700° C. by using a material combination of mono-silane and ammonium gas.

8. The method of manufacturing a semiconductor device according to claim 6, wherein
the silicon nitride layer is deposited at a flow ratio of ammonium gas to mono-silane ranging from 25 to 133.

9. The method of manufacturing a semiconductor device according to claim 1, wherein
the silicon nitride layer is deposited at a temperature of not higher than 700° C. by using a material combination of di-silane and ammonium gas.

10. The method of manufacturing a semiconductor device according to claim 1, wherein
the silicon nitride layer is deposited at a temperature ranging from 500° C. to 650° C. by using a material combination of di-silane and ammonium gas.

11. The method of manufacturing a semiconductor device according to claim 9, wherein
the silicon nitride layer is deposited at a flow ratio of ammonium gas to di-silane ranging from 25 to 350.
